(19) United States
(12) Patent Application Publication
(10) Pub. No.: US 2005/0136595 A1
(43) Pub. Date: Jun. 23, 2005

(54) Method for manufacturing semiconductor device

(76) Inventor: Tomokazu Horie, Sakata-shi (JP)

Correspondence Address: HARNESS, DICKEY & PIERCE, P.L.C., P.O. BOX 828, BLOOMFIELD HILLS, MI, 48303, US

(21) Appl. No.: 11/020,005

(22) Filed: Dec. 21, 2004

(30) Foreign Application Priority Data
Dec. 22, 2003 (JP) 2003-424702

(51) Int. Cl. H01L 29/04; H01L 31/036; H01L 21/31; H01L 31/0376

(52) U.S. Cl. 438/257; 438/775

(57) ABSTRACT

A method for manufacturing a semiconductor device is provided including the steps of covering the first nitride film formed on the first oxide film within the first region where the first gate insulation film for the first transistor that operates at one voltage is to be formed; performing plasma nitridation for the second nitride film, having a thickness virtually the same as that of the first nitride film, formed on the second oxide film within the second region where the second gate insulation film for the second transistor that operates at another voltage lower than the one voltage is to be formed; and growing the second nitride film.

### RELATED APPLICATIONS

This application claims priority to Japanese Patent Application No. 2003-424702 filed Dec. 22, 2003 which is hereby expressly incorporated by reference herein in its entirety.

### BACKGROUND

1. Field of the Invention

The present invention relates to a method for manufacturing a semiconductor device comprising a plurality of transistors that operate at different voltages.

2. Related Art

Conventionally, there is a semiconductor device, as one of the semiconductor devices described above, comprising a transistor that operates at a low voltage (hereinafter referred to as “low-voltage transistor”) and a transistor that operates at a high voltage (hereinafter referred to as “high-voltage transistor”). Both transistors are required to have a gate insulation film having insulating characteristics in accordance with the above operating voltages.

FIG. 6 is a cross-sectional view of a method for manufacturing the above conventional semiconductor device. The method for manufacturing the conventional semiconductor device will now be described in detail referring to FIG. 6.

Step S30: After forming an element isolation film 101 on a silicon substrate 100, deposit an oxide film (not illustrated) on the entire surface of the silicon substrate 100 by means of thermal oxidation. Then by performing photolithography and etching, form an oxide film 130 within a region 110 where the gate insulation film of the low-voltage transistor is to be formed, as illustrated, and further form a gate oxide film 140 of the high-voltage transistor within a region 120 where the gate insulation film of the high-voltage transistor is to be formed.

Step S31: After applying a photoresist 102 on the entire surface of the silicon substrate 100, make an opening at a portion 102a that approximately corresponds to the oxide film 130 by means of photolithography and, at the same time, leave a portion 102b that approximately corresponds to the gate oxide film 140.

Step S32: After removing the oxide film 130 by performing etching, remove the photoresist 102b.

Step S33: By performing thermal oxidation, form a gate oxide film 150 of the low-voltage transistor, which is thinner than the gate oxide film 120, and, at the same time, grow the gate oxide film 140 of the high-voltage transistor slightly.

Step S34: By performing plasma nitridation, form a gate nitride film 160 on the gate oxide film 150 and, at the same time, form a gate nitride film 170, having a thickness approximately the same as that of the gate nitride film 160, on the gate oxide film 140. That is, in the conventional semiconductor device, the gate insulation film of the high-voltage transistor comprises the gate oxide film 140 and the gate nitride film 170, and the gate insulation film of the low-voltage transistor comprises the gate oxide film 150 and the gate nitride film 160 having a thickness approximately the same as that of the gate nitride film 170.

Generally, from the viewpoint that a low-voltage transistor must operate at a low voltage, “thinness” is required for a gate insulation film of the low-voltage transistor. That is, thinness is required for the gate oxide film 150. On the other hand, from the viewpoints of gate leak and reliability (including aging due to negative bias temperature instability (NBTI)) as well as prevention of impurity penetration, “thickness” is required.

Here, “gate leak” means that an electric current runs through the gate insulation film and between a source electrode and a gate electrode because the gate insulation film is thin. Also, “impurity penetration” means that impurities penetrate through the gate insulation film and reach a semiconductor substrate, because the gate insulation film is thin, when the impurities are driven into the gate electrode from above in order to reduce the resistance of the gate electrode or when the transistor starts to operate.

However, in the above method for manufacturing the conventional semiconductor device, the thickness of the gate nitride film 160 of the low-voltage transistor cannot be made thicker than that of the nitride film 170 of the high-voltage transistor. Therefore, in the low-voltage transistor, there has been a problem that the reduction of the above-described gate leak becomes insufficient because the gate oxide film 150 and gate nitride film 160 of the low-voltage transistor are thin.

### SUMMARY

In order to solve the above problem, a method for manufacturing the first semiconductor device according to the present invention comprises the steps of covering the first nitride film formed on the first oxide film within the first region where the first gate insulation film for the first transistor that operates at one voltage is to be formed; performing plasma nitridation for the second nitride film, having a thickness virtually the same as that of the first nitride film, formed on the second oxide film within the second region where the second gate insulation film for the second transistor that operates at another voltage lower than the one voltage is to be formed; and growing the second nitride film.

Based on the method for manufacturing the first semiconductor device according to the present invention, by performing plasma nitridation for the second nitride film for the second transistor that operates at a relatively low voltage, with the first nitride film covered, the thickness of the second nitride film is made thicker than that of the first nitride film, and therefore the occurrence of the above-described gate leak and impurity penetration can be reduced.

A method for manufacturing the second semiconductor device according to the present invention comprises the steps of covering the first oxide film within the first region, where the first gate insulation film for the first transistor that operates at one voltage is to be formed, with a mask having a plurality of holes piercing from the top surface through to the bottom surface, by placing the bottom surface of the mask facing the first oxide film; forming the first nitride film on the first oxide film by performing plasma nitridation for the first oxide film and the second oxide film within the second region where the second gate insulation film for the second transistor that operates at another voltage lower than the one voltage is to be formed; and forming, on the second oxide film, the second nitride film thicker than the first nitride film.

Based on the method for manufacturing the second semiconductor device according to the present invention, by performing plasma nitridation for the first oxide film and the second oxide film for the second transistor that operates at a relatively low voltage, with the first oxide film covered with the mask having a plurality of holes, the thickness of the second nitride film formed on the second oxide film is made thicker than that of the first nitride film formed on the first oxide film, and therefore the occurrence of gate leak and impurity penetration can be reduced in the same manner as described in the method for manufacturing the first semiconductor device according to the present invention.

In the above method for manufacturing the second semiconductor device according to the present invention, it is desirable that the plurality of holes of the mask are formed in a shape of a slit or a lattice.

### BRIEF DESCRIPTION OF THE DRAWINGS

FIG. 1 is a drawing of a method for manufacturing a semiconductor device according to the first embodiment (the first half).

FIG. 2 is a drawing of a method for manufacturing a semiconductor device according to the first embodiment (the second half).

FIG. 3 is a drawing of a method for manufacturing a semiconductor device according to the second embodiment (the first half).

FIG. 4 is a drawing of a method for manufacturing a semiconductor device according to the second embodiment (the second half).

FIGS. 5A and B are drawings of a mask according to the second embodiment.

FIG. 6 is a drawing of a method for manufacturing the conventional semiconductor device.

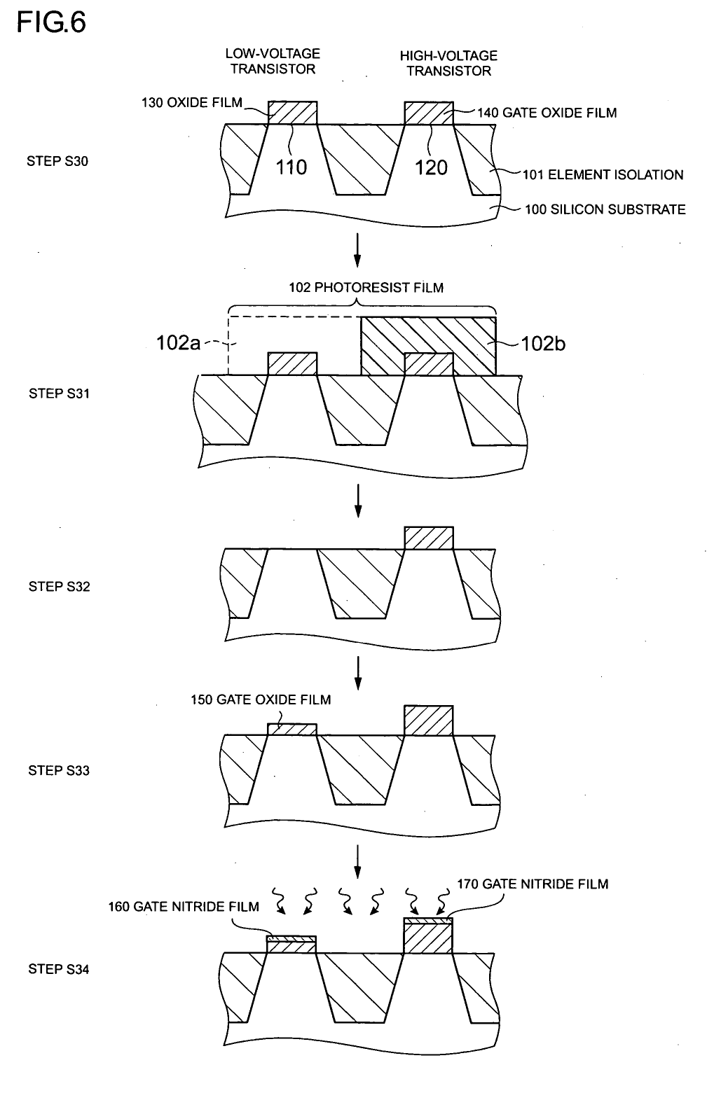

### DETAILED DESCRIPTION

Embodiments of the method for manufacturing a semiconductor device according to the present invention will now be described in detail referring to the accompanying drawings. Semiconductor devices according to the first embodiment and the second embodiment have, the same as the semiconductor device described in Background, a low-voltage transistor and a high-voltage transistor, while the thickness of a gate nitride film for the low-voltage transistor is thicker than that of the high-voltage transistor.

### FIRST EMBODIMENT

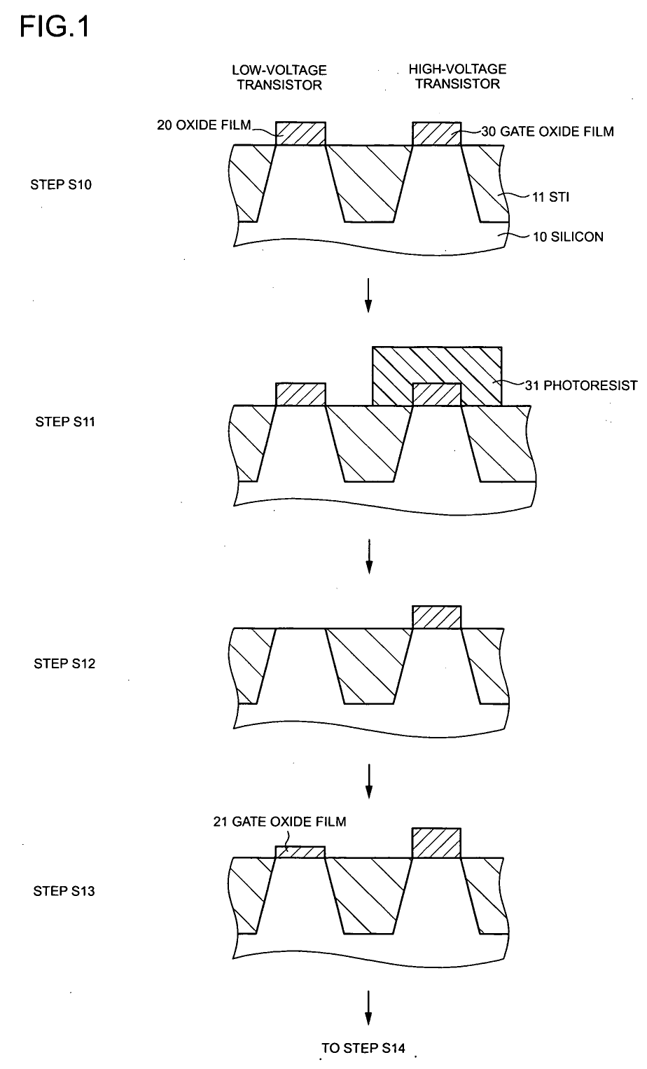

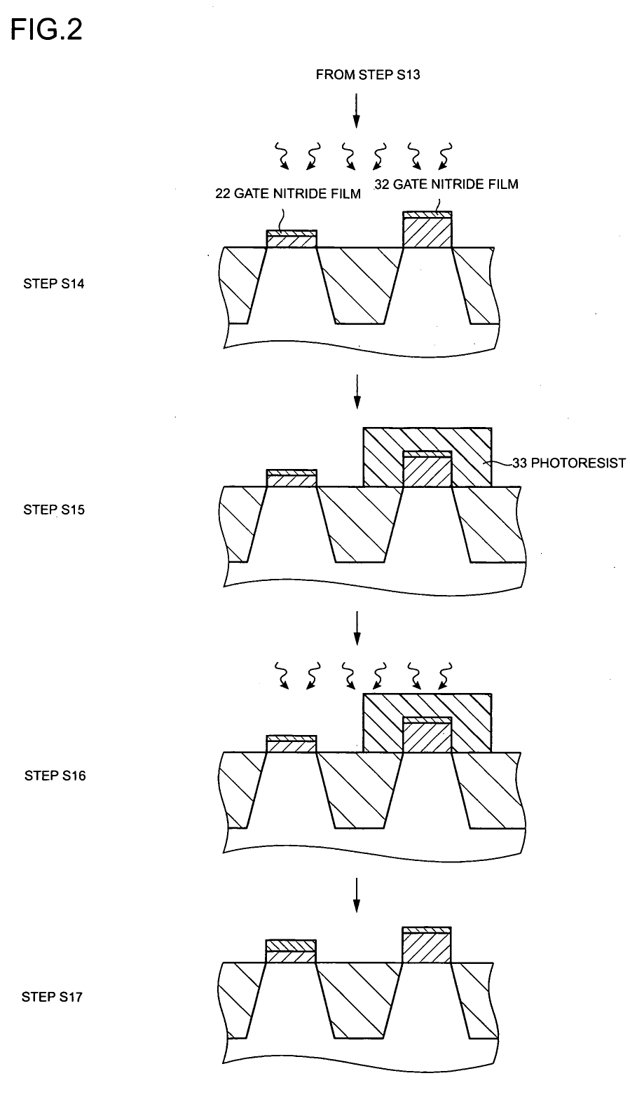

FIG. 1 and FIG. 2 are cross-sectional views of a method for manufacturing a semiconductor device according to the first embodiment. The method for manufacturing a semiconductor device according to the first embodiment will now be described in detail referring to FIG. 1.

Step S10: On a surface-polished silicon substrate 10, on which an element isolation film of a shallow trench isolation (STI) film 11 is formed, form an oxide film (not illustrated) that is the original of a gate oxide film 30 of the high-voltage transistor by means of thermal oxidation. Then, by perform photolithography and etching for the relevant oxide film, form an oxide film 20 and a gate oxide film 30 of the high-voltage transistor, each of which takes an approximate rectangular shape as illustrated, within a region where a gate insulation film of the low-voltage transistor is to be formed and a region where a gate insulation film of the high-voltage transistor is to be formed.

Step S11: After applying photoresist (not illustrated) on the entire surfaces of the silicon substrate 10, oxide film 20 and gate oxide film 30, followed by exposure using a mask (not illustrated) that is patterned so that only a part of the photoresist 31 approximately corresponding to the gate oxide film 30 may remain, perform etching. Thus, make the oxide film 20 exposed and, at the same time, coat the gate oxide film 30 with the photoresist 31.

Step S12: By performing wet etching using an etching solution including, for example, hydrofluoric acid on the entire surface of the silicon substrate 10, remove the oxide film 20. Further, dissolve and remove the photoresist 31.

Step S13: By performing thermal oxidation, deposit a gate oxide film 21 of the low-voltage transistor and, at the same time, grow the gate oxide film 30 of the high-voltage transistor slightly.

Step S14: By performing plasma nitridation, grow a gate nitride film 22 and a gate nitride film 32, which have the same thickness, on the gate oxide film 21 of the low-voltage transistor and the gate oxide film 30 of the high-voltage transistor.

Step S15: After applying photoresist (not illustrated) on the entire surfaces of the silicon substrate 10, gate nitride film 22 and gate nitride film 32, followed by exposure using a mask (not illustrated) that is patterned so that only a part of the photoresist 33 approximately corresponding to the gate nitride film 32 may remain, perform etching. Thus, make the gate nitride film 22 of the low-voltage transistor exposed and, at the same time, coat the nitride film 32 of the high-voltage transistor with the photoresist 33.

Step S16: By performing the same plasma nitridation as that in Step S14 and thus growing the gate nitride film 22 of the low-voltage transistor, make the gate nitride film 22 of the low-voltage transistor thicker than the gate nitride film 32 of the high-voltage transistor.

Step S17: Remove the photoresist 33.

As described above, in the method for manufacturing a semiconductor device according to the first embodiment, since the gate nitride film 32 of the high-voltage transistor is coated with the photoresist 33 and, with the nitride film 22 of the low-voltage transistor exposed, plasma nitridation is performed on the entire surface of the silicon substrate 10, the gate nitride film 22 of the low-voltage transistor can be grown without growing the gate nitride film 32 of the high-voltage transistor. That is, the gate nitride film 22 of the low-voltage transistor can be made thicker than the gate nitride film 32 of the high-voltage transistor, which makes it possible to control the occurrence of gate leak and impurity penetration on the low-voltage transistor.

### SECOND EMBODIMENT

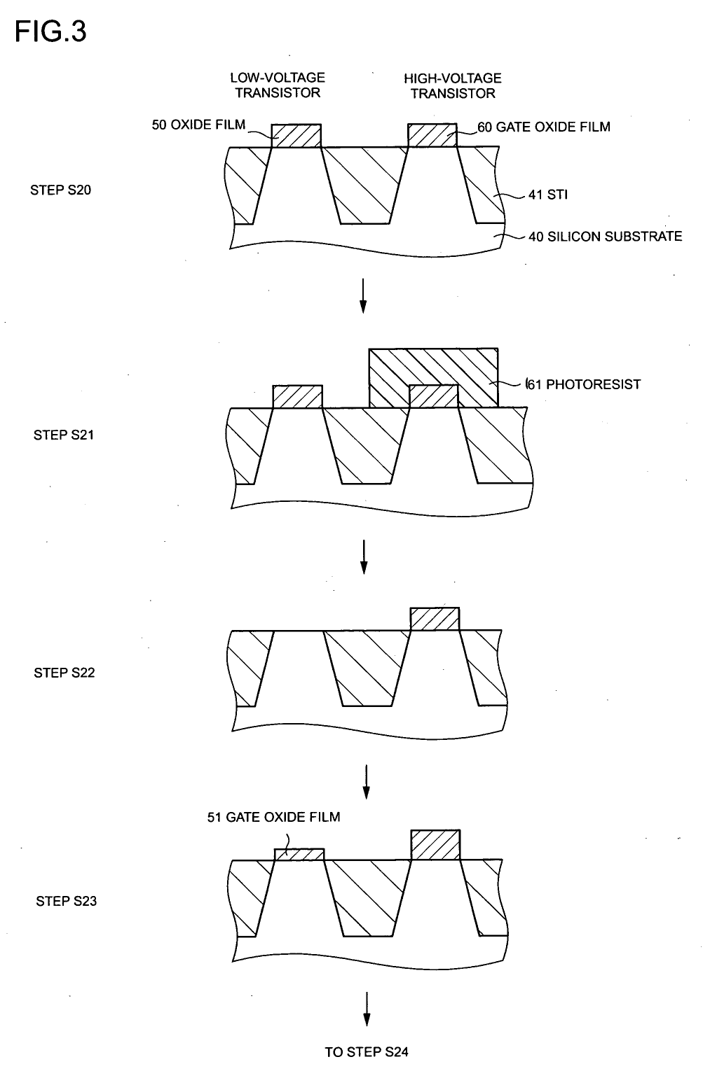

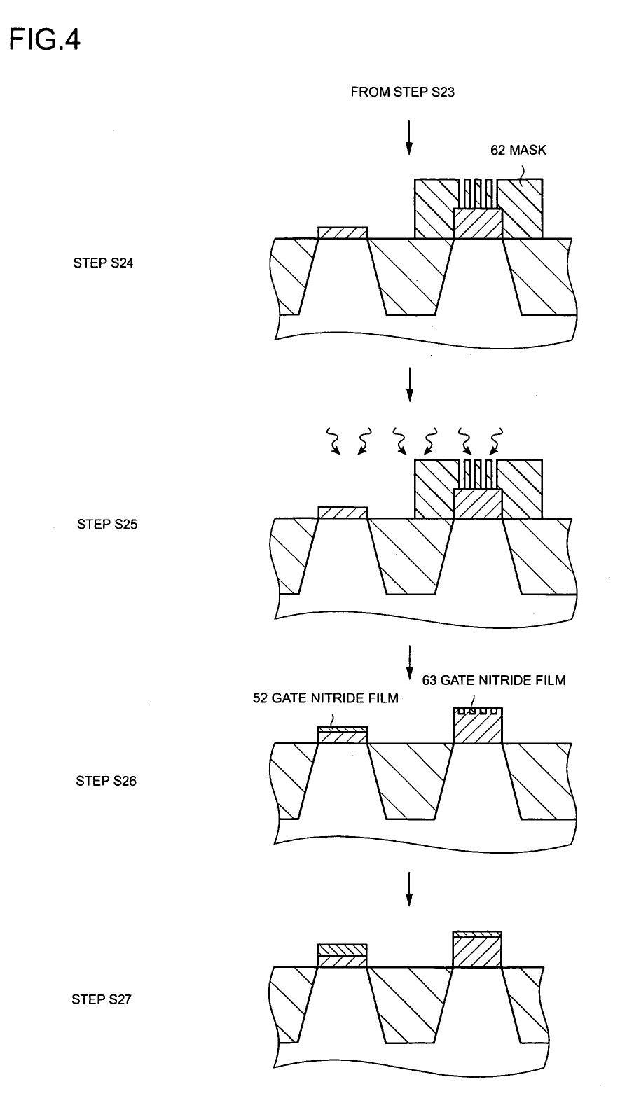

FIG. 3 and FIG. 4 are cross-sectional views of a method for manufacturing a semiconductor device according to the second embodiment. The method for manufacturing a semiconductor device according to the second embodiment will now be described in detail referring to FIG. 3 and FIG. 4.

Step S20: On a surface-polished silicon substrate 40, on which an STI film 41 is formed, form an oxide film (not illustrated) that is the original of a gate oxide film 40 of the high-voltage transistor by means of thermal oxidation. Then, by perform photolithography and etching for the relevant oxide film, form an oxide film 50 and a gate oxide film 60 of the high-voltage transistor, each of which takes an approximate rectangular shape as illustrated, within a region where a gate insulation film of the low-voltage transistor is to be formed and a region where a gate insulation film of the high-voltage transistor is to be formed.

Step S21: After applying photoresist (not illustrated) on the entire surfaces of the silicon substrate 40, oxide film 50 and gate oxide film 60, followed by exposure using a mask (not illustrated) that is patterned so that only a portion approximately corresponding to the gate oxide film 60 may remain, perform etching. Thus, make the oxide film 50 exposed and, meanwhile, coat the gate oxide film 60 of the high-voltage transistor with the photoresist 61.

Step S22: By performing wet etching on the entire surface of the silicon substrate 40, remove the oxide film 50. Further, remove the photoresist 61.

Step S23: By performing thermal oxidation, deposit a gate oxide film 51 of the low-voltage transistor.

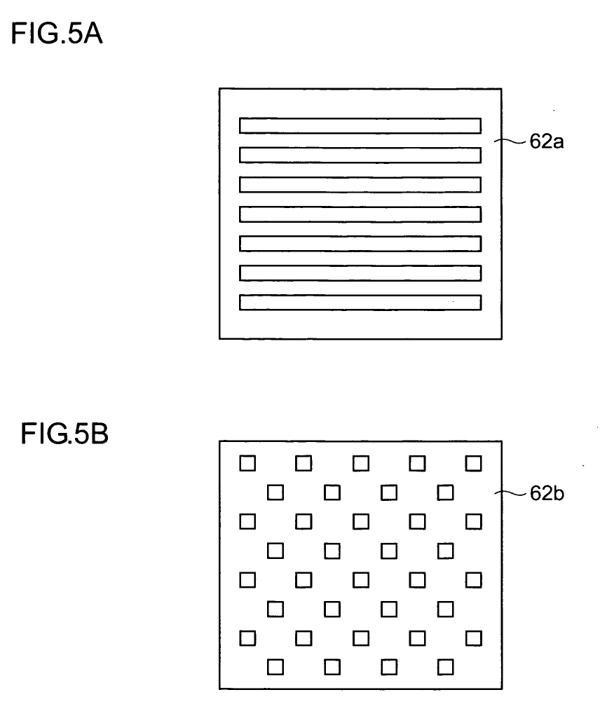

Step S24: Cover the gate oxide film 60 with a mask having a plurality of holes piercing from the top surface to the bottom surface, more specifically, a mask 62, which is a mask 62a having a plurality of parallel slits as shown in FIG. 5A, or a mask 62b having a plurality of rectangular holes that are placed in a lattice shape as shown in FIG. 5B.

Step S25: Perform plasma nitridation with the gate oxide film 50 entirely exposed and the gate oxide film 60 partially exposed by the mask 62. Thus, form a gate nitride film 52 on the entire surface of the gate oxide film 50 and, at the same time, dispersively form a gate nitride film 63 on the surface of the gate oxide film 60.

Step S26: Remove the mask 62.

Step S27: In order to diffuse and stabilize the gate nitride film 63 on the gate oxide film 60, perform annealing.

As described above, in the method for manufacturing a semiconductor device according to the second embodiment, since plasma nitridation is performed with the gate oxide film 60 of the high-voltage transistor covered with the mask 62 having a plurality of holes piercing between the top surface and the bottom surface and also with the gate oxide film 50 of the low-voltage transistor exposed, the gate nitride film 63 having a thickness in accordance with the size and layout pattern of slits or lattice-shaped holes can be formed on the gate oxide film 60 of the high-voltage transistor, and further the gate nitride film 52 thicker than the gate nitride film 63 of the high-voltage transistor can be formed on the gate oxide film 50 of the low-voltage transistor. Thus, the same as the method for manufacturing a semiconductor device according to the first embodiment, it becomes possible to control the occurrence of gate leak and impurity penetration on the low-voltage transistor.

1. A method for manufacturing a semiconductor device, comprising the steps of:
covering a first nitride film formed on a first oxide film within a first region where a first gate insulation film for a first transistor that operates at one voltage is to be formed;
performing plasma nitridation for a second nitride film, having a thickness virtually the same as that of the first nitride film, formed on a second oxide film within a second region where a second gate insulation film for a second transistor that operates at another voltage lower than the one voltage is to be formed; and
growing the second nitride film.

2. A method for manufacturing a semiconductor device, comprising the steps of:
covering a first oxide film within a first region, where a first gate insulation film for a first transistor that operates at one voltage is to be formed, with a mask having a plurality of holes piercing from a top surface through to a bottom surface, by placing the bottom surface of the mask facing the first oxide film;
forming a first nitride film on the first oxide film by performing plasma nitridation for the first oxide film and a second oxide film within a second region where a second gate insulation film for a second transistor that operates at another voltage lower than the one voltage is to be formed; and
forming, on the second oxide film, a second nitride film thicker than the first nitride film.

3. A method for manufacturing a semiconductor device, wherein the plurality of holes are formed in a shape of a slit or a lattice.
